(19) United States
(12) Patent Application Publication
(10) Pub. No.: US 2026/0205120 A1
(43) Pub. Date: Jul. 16, 2026

(54) CIRCUIT STACKING FOR LOW POWER DESIGN

(71) Applicant: STMicroelectronics International N.V., Geneva (CH)

(72) Inventors: Ankur BAL, Greater Noida (IN); Jeet Narayan TIWARI, Greater Noida (IN)

(21) Appl. No.: 19/448,976

(22) Filed: Jan. 14, 2026

Related U.S. Application Data
(60) Provisional application No. 63/745,687, filed on Jan. 15, 2025.

(51) Int. Cl. H03K 19/0175; H03K 3/037

(52) U.S. Cl. CPC H03K 19/017509; H03K 3/037

(57) ABSTRACT

Embodiments of the present disclosure provide techniques for low power design. A low power digital circuit system may include a high speed digital circuit. A first supply voltage may be applied to the high speed digital circuit. The digital circuit system may include a circuit stack that includes a first low speed digital circuit and a second low speed digital circuit stacked vertically on top relative to the first low speed digital circuit. Each of the first low speed digital circuit and the second low speed digital circuit may be configured for being driven at a second supply voltage that is less than the first supply voltage, and may be connected at a central node with a node voltage that is substantially same as the second supply voltage. The digital circuit system may include a load balancing circuit and one or more level shifter components.

### CROSS-REFERENCE TO RELATED APPLICATIONS

This application claims priority to U.S. Provisional Patent Application No. 63/745,687, filed on January 15, 2025, which is incorporated herein by reference in its entirety.

### FIELD OF THE INVENTION

The present disclosure relates to low power design and, more particularly, to circuit. stacking for low power design. Some example embodiments relate to low power design in systems comprising digital circuits of various speeds.

### BACKGROUND

Applicant has identified many technical challenges and difficulties associated with low power design in systems. Through applied effort, ingenuity, and innovation, Applicant has solved many of these identified problems by developing the embodiments of the present disclosure, which are described in detail below.

### BRIEF SUMMARY

Various embodiments described herein relate to low power design and, more particularly, to circuit. stacking for low power design.

In accordance with one aspect of the present disclosure, a digital circuit system is provided. In an example embodiment, the digital circuit system comprises a high speed digital circuit, wherein a first supply voltage is being applied to the high speed digital circuit; a circuit stack comprising a first low speed digital circuit and a second low speed digital circuit stacked vertically on top relative to the first low speed digital circuit, wherein each of the first low speed digital circuit and the second low speed digital circuit are (i) configured for being driven at a second supply voltage that is less than the first supply voltage, and (ii) are connected at a central node with a node voltage that is substantially same as the second supply voltage; and one or more level shifter components configured for transitioning between the first supply voltage and the second supply voltage.

In some embodiments, the first low speed digital circuit and the second low speed digital circuit are connected in series.

In some embodiments, the node voltage is a fraction of the first supply voltage based on a number of low speed digital circuits in the circuit stack.

In some embodiments, the high speed digital circuit is configured for being driven at the first supply voltage.

In some embodiments, at least one of the first low speed digital circuit or the second low speed digital circuit comprise a synchronous circuit.

In some embodiments, at least one of the first low speed digital circuit or the second low speed digital circuit comprise an asynchronous circuit.

In some embodiments, the circuit stack comprises a load balancing circuit configured to maintain the node voltage.

In some embodiments, the circuit stack further comprises one or more dummy circuits, wherein the load balancing circuit is configured to detect instantaneous unequal current demand with respect to the circuit stack, and enforce toggling in response to detecting the unequal current demand using at least a portion of the one or more dummy circuits.

In some embodiments, a first dummy circuit of the one or more dummy circuits comprise a portion of the second low speed digital circuit.

In some embodiments, a second dummy circuit of the one or more dummy circuits comprise a portion of the first low speed digital circuit.

In accordance with one aspect of the present disclosure, a digital circuit system is provided. In an example embodiment, the digital circuit system comprises one or more mixed signal circuits, wherein a first supply voltage is being applied to the one or more mixed signal circuits; a circuit stack comprising a first full speed digital circuit and a second full speed digital circuit stacked vertically on top relative to the first full speed digital circuit, wherein each of the first full speed digital circuit and the second full speed digital circuit are (i) configured for being driven at a second supply voltage that is less than the first supply voltage, and (ii) are connected at a central node with a node voltage that is substantially same as the second supply voltage; and one or more level shifter components configured for transitioning between the first supply voltage and the second supply voltage.

In some embodiments, the first full speed digital circuit and the second full speed digital circuit are connected in series.

In some embodiments, the node voltage is a fraction of the first supply voltage based on a number of full speed digital circuits in the circuit stack.

In some embodiments, the one or more mixed signal circuits is configured for being driven at the first supply voltage.

In some embodiments, at least one of the first full speed digital circuit or the second full speed digital circuit comprise a synchronous circuit.

In some embodiments, at least one of the first full speed digital circuit or the second full speed digital circuit comprise an asynchronous circuit.

In some embodiments, the one or more mixed signal circuits comprise one or more ADCs.

In some embodiments, the circuit stack further comprises a load balancing circuit configured to maintain the node voltage and one or more dummy circuits, wherein the load balancing circuit is configured to detect instantaneous unequal current demand with respect to the circuit stack, and enforce toggling in response to detecting the unequal current demand using at least a portion of the one or more dummy circuits.

In some embodiments, a first dummy circuit of the one or more dummy circuits comprises a portion of the second full speed digital circuit.

In some embodiments, a second dummy circuit of the one or more dummy circuits comprises a portion of the first full speed digital circuit.

### BRIEF DESCRIPTION OF THE DRAWINGS

The description of the illustrative embodiments may be read in conjunction with the accompanying figures. It will be appreciated that, for simplicity and clarity of illustration, elements illustrated in the figures have not necessarily been drawn to scale, unless described otherwise. For example, the dimensions of some of the elements may be exaggerated relative to other elements, unless described otherwise. Embodiments incorporating teachings of the present disclosure are shown and described with respect to the figures presented herein, in which:

FIG. 1 provides a block diagram an example system in which example circuit stacking techniques may be implemented according to at least some embodiments of the present disclosure.

FIG. 2 provides a block diagram of an example low power digital circuit system in accordance with at least some embodiments of the present disclosure.

FIG. 3a provides an example canary circuit in accordance with at least some embodiments of the present disclosure.

FIG. 3b provides an example dummy circuit in accordance with at least some embodiments of the present disclosure.

FIG. 4 provides a block diagram of an example low power mixed signal digital circuit system in accordance with at least some embodiments of the present disclosure.

FIG. 5 provides an example multi-phase clock generator in accordance with at least some embodiments of the present disclosure.

FIG. 6 provides an example moving average filter with stacked filters in accordance with at least some embodiments of the present disclosure.

### DETAILED DESCRIPTION OF THE INVENTION

Some embodiments of the present disclosure will now be described more fully hereinafter with reference to the accompanying drawings, in which some, but not all embodiments of the disclosure are shown. Indeed, these disclosures may be embodied in many different forms and should not be construed as limited to the embodiments set forth herein; rather, these embodiments are provided so that this disclosure will satisfy applicable legal requirements. Like numbers refer to like elements throughout.

Terms such as “computing,” “determining,” “generating,” and/or similar words are used herein interchangeably to refer to the creation, modification, or identification of data. Further, “based on,” “based on in part on,” “based at least on,” “based upon,” and/or similar words are used herein interchangeably in an open-ended manner such that they do not indicate being based only on or based solely on the referenced element or elements unless so indicated. Like numbers refer to like elements throughout.

As used herein, terms such as “front,” “rear,” “top,” etc. are used for explanatory purposes in the examples provided below to describe the relative position of certain components or portions of components. Furthermore, as would be evident to one of ordinary skill in the art in light of the present disclosure, the terms “substantially” and “approximately” indicate that the referenced element or associated description is accurate to within applicable engineering tolerances.

As used herein, the term “comprising” means including but not limited to and should be interpreted in the manner it is typically used in the patent context. Use of broader terms such as comprises, includes, and having should be understood to provide support for narrower terms such as consisting of, consisting essentially of, and comprised substantially of.

The phrases “in one embodiment,” “according to one embodiment,” and the like generally mean that the particular feature, structure, or characteristic following the phrase may be included in at least one embodiment of the present disclosure, and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments, or it may be excluded.

As used herein, the term “or” is used in both the alternative and conjunctive sense, unless otherwise indicated. The terms “illustrative” and “example” are used to be examples with no indication of quality level. Terms such as “computing,” “determining,” “generating,” and/or similar words are used herein interchangeably to refer to the creation, modification, or identification of data. Further, “based on,” “based on in part on,” “based at least on,” “based upon,” and/or similar words are used herein interchangeably in an open-ended manner such that they do not indicate being based only on or based solely on the referenced element or elements unless so indicated. Like numbers refer to like elements throughout.

With technology scaling, increase in transistor density and high frequency operation, there is a need to reduce power dissipation, particularly in modern chips. In various applications and systems, including systems on chip or very-large-scale integration that include multiple digital circuits on a single integrated circuit (IC), there is a need to reduce the power consumption of the IC. For example, many power-sensitive electronic device such as battery-powered electronic devices (e.g., Internet-of Things (IOT) devices, handheld devices, and/or the like) include such ICs to facilitate and/or perform various functionalities (e.g., data processing, communication, or the like).

Moreover, increasing number of functionalities are being added to electronic devices, including power-sensitive electronic devices, to improve the capabilities of these electronic devices. This often involves increased number of digital circuits on a single IC and/or increased number of ICs used in the electronic device. In this regard, a need exists for improving low power design in electronic devices and systems to improve the life of the power source of the electronic devices and system such as, for example, battery life.

Embodiments of the present disclosure relate to low power designs, including low power design for electronic devices and systems that include multiple digital circuits on an IC and/or multiple ICs. Digital circuits may comprise switches, flip-flops, counters, memory devices, registers, logic gates, and/or the like. In many examples, a digital circuit (or portion thereof) may be implemented as and/or comprise metal oxide semiconductor field-effect transistor (MOSFET) transistors, such as complementary metal-oxide-semiconductor (CMOS). For example, in some implementations a digital circuit may comprise one or more CMOS devices (e.g., CMOS inverter or the like) that function as logic gates, switches, and/or the like. An example of such CMOS device is a CMOS inverter.

The total power consumed by a digital circuit may depend on the supply voltage (V_{DD})applied to the digital circuit, particularly, for digital circuits that include MOSFET devices such as CMOS or other transistors. The components of power such as load power, short circuit power, and leakage power may be proportional to the supply voltage (V_{DD})or some multiple of the supply voltage. For example, for a CMOS inverter, the load power may be represented as “C_{L} V_{DD}²” (thus proportional to the square of the supply voltage), the short circuit power may be represented as “t_{sc}V_{DD}Iₚₑₐₖ” (thus proportional to the supply voltage), and/or the leakage power may be represented by “V_{DD}I_{leakage}” (thus proportional to the supply voltage).

Example embodiments of the present disclosure provide circuit stacking techniques that reduce the voltage supply applied to a digital circuit, which in turn reduces the individual power components and thus, the overall power consumed by the digital circuit. Additionally, the circuit stacking techniques of example embodiments of the present disclosure obviate the need for voltage regulators, such as low drop out (LDO) regulators, to reduce the supply voltage applied to a digital circuit. While voltage regulators may reduce supply voltage, they dissipate some power and thus provide reduced power efficiency (e.g., output power relative to input power). In this regard, by obviating the need for voltage regulators, example embodiments of the present disclosure further reduce power consumption and provide increased power efficiency.

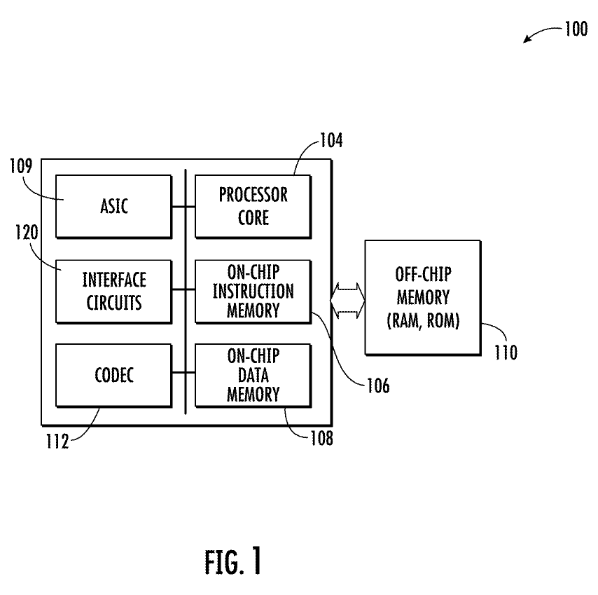

FIG. 1 provides a block diagram of an example system 100 in which example circuit stacking techniques may be implemented according to at least some embodiments of the present disclosure. The depiction of the example system 100 is not intended to limit or otherwise confine the embodiments described and contemplated herein to any particular configuration of elements or systems, nor is it intended to exclude any alternative configurations or systems for the set of configurations and systems that can be used in connection with embodiments of the present disclosure. Rather, FIG. 1 and the system 100 disclosed therein is merely presented to provide an example basis and context for the facilitation of some of the features, aspects, and uses of the methods, apparatuses, and systems disclosed and contemplated herein. It will be understood that while many of the aspects and components presented in FIG. 1 are shown as discrete, separate elements, other configurations may be used, including configurations that combine, omit, separate, and/or add aspects and/or components.

The system 100 may represent a system associated with an electronic device. The system 100 may comprise a partitioned system architecture. For example, the system 100 may be partitioned into hardware and software to reduce power. The system 100 may be partitioned based on a system specification for the system 100. In the illustrated example, the system 100 may include a processor core 104, one or more memories such as on-chip instruction memory 106, on-chip data memory 108, off-chip memory 110 (e.g., RAM, ROM, and/or the like), one or more code converters 112 (e.g., codec or the like), one or more interface circuits 120, and/or one or more application-specific integrated circuits (ASICs) 109.

According to example embodiments of the present disclosure, one or more of the components of the system 100, such as the ASIC 109, processor core 104, and/or the like may be analyzed and circuit stacking techniques may be implemented in one or more of the analyzed components of the partitioned system 100 as described herein to further reduce power.

As described above, traditional low power design techniques may include a voltage regulator, such as an LDO regulator implemented to step down (e.g., drop) the voltage supply (V_{DD})However, such techniques dissipate power. Example embodiments, of the present disclosure implement circuit stacking techniques that obviate the need for voltage regulators designed to reduce supply voltage and in addition leverages the power that would otherwise have been dissipated by a voltage regulator to drive/run another circuit, thus increasing power efficiency.

In various applications, the circuit stacking techniques described herein may be incorporated and/or used with other low power design techniques such as, but not limited to, multi voltage reduction technique, power gating, clock gating, and/or the like.

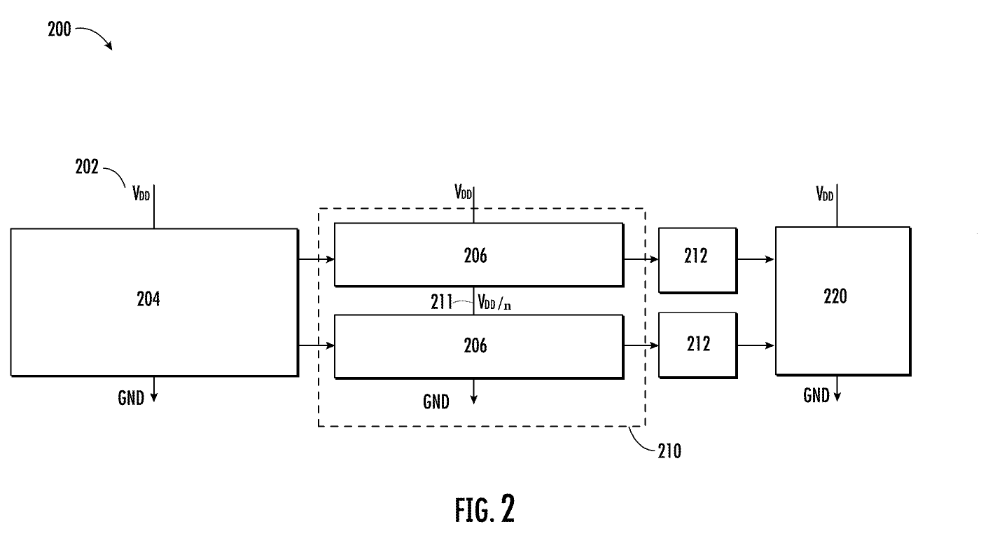

FIG. 2 provides a block diagram of an example low power digital circuit system 200 in accordance with at least some embodiments of the present disclosure. FIG. 2 may represent a portion of an example integrated circuit associated with an electronic device or system implementing circuit stacking techniques according to at least some embodiments of the present disclosure.

The depiction of the example low power digital circuit system 200 is not intended to limit or otherwise confine the embodiments described and contemplated herein to any particular configuration of elements or systems, nor is it intended to exclude any alternative configurations or systems for the set of configurations and systems that can be used in connection with embodiments of the present disclosure. Rather, FIG. 2 and the low power digital circuit system 200 disclosed therein is merely presented to provide an example basis and context for the facilitation of some of the features, aspects, and uses of the methods, apparatuses, and systems disclosed and contemplated herein. It will be understood that while many of the aspects and components presented in FIG. 2 are shown as discrete, separate elements, other configurations may be used, including configurations that combine, omit, separate, and/or add aspects and/or components.

In various embodiments, the low power digital circuit system 200 may comprise one or more high speed digital circuits 204 and/or one or more low speed digital circuits 206. For example, the illustrated example of FIG. 2 may comprise a system of digital circuits representative of the low power digital circuit system 200 configured to perform one or more functionalities. In some embodiments, the high speed digital circuits 204 may be connected to the one or more low speed digital circuits 206. For example, the one or more high speed digital circuits 204 may be connected to a stack of low speed digital circuits 206, as further described below. In some embodiments, the high speed digital circuits 204 may be connected in parallel to the one or more low speed digital circuits 206 (e.g., stack of low speed digital circuits 206).

In some embodiments, a high speed digital circuit 204 may comprise a digital circuit configured to operate at a speed that exceeds a predefined threshold, which may depend on the application and/or system specifications. In some embodiments, a high speed digital circuit 204 may comprise a digital circuit configured to operate at a speed that is greater than a speed of one or more other digital circuits in a system or IC comprising the high speed digital circuit.

In some embodiments, a low speed digital circuit 206 may comprise a digital circuit configured to operate at a speed that is below a predefined threshold, which may depend on the application and/or system specifications. In some embodiments, a low speed digital circuit 206 may comprise a digital circuit configured to operate at a speed that is less than a speed of one or more other digital circuits in a system or IC comprising the low speed digital circuit. In some embodiments, a low speed digital circuit 206 as described herein may encompass medium speed digital circuits. For example, in some embodiments a low speed digital circuit may describe a low speed digital circuit and/or a medium speed digital circuit.

The one or more high speed digital circuits 204 may require high supply voltage while the one or more low speed digital circuits 206 may not require such high voltages. In some embodiments, the one or more high speed digital circuits 204 are configured to operate, run, or otherwise driven at a supply voltage that is greater than a supply voltage at which the one or more low speed digital circuits 206 are configured to operate, run, or otherwise driven. In such some embodiments, a low speed digital circuit 206 may be configured to operate, run, or otherwise driven at a supply voltage that is less than the one or more high speed digital circuits 204. In one example, the one or more high speed digital circuits 204 may be configured to operate, run or otherwise driven at a supply voltage (V_{DD}) 202 of 1.2V. In some embodiments, the supply voltage 202 of the one or more high speed digital circuits 204 corresponds to the supply voltage applied to the digital circuit system and/or IC in which the one or more high speed digital circuits 204 are embodied and/or may be a constant supply voltage from the voltage source. The supply voltage (V_{DD}) 202 may be generated or supplied from a variety of voltage source types such as, but not limited to, batteries, DC-DC converter, and/or the like.

The digital circuit system 200 and/or the circuit stack 210 thereof may comprise any of a plurality of circuit types such as, but not limited to synchronous circuits, asynchronous circuits, and/or the like. In some embodiments, at least a portion of the digital circuit system 200 may comprise a synchronous circuit. For example, a low speed digital circuit and/or a high speed digital circuit thereof may comprise a synchronous circuit. In some embodiments, at least one of the low speed digital circuits in the circuit stack 210 comprises a synchronous circuit. Additionally, or alternatively, in some embodiments, at least a portion of the digital circuit system 200 may comprise an asynchronous circuit. For example, a low speed digital circuit and/or a high speed digital circuit thereof may comprise an asynchronous circuit. In some embodiments, at least one of the low speed digital circuits in the circuit stack 210 comprises an asynchronous circuit. In this regard, the circuit stack 210 may comprise any of a plurality of circuit types. For example, in some embodiments, some or all of the digital circuits 206 in the circuit stack 210 may each comprise a synchronous circuit. As another example, in some embodiments, some or all of the digital circuits 206 in the circuit stack 210 may each comprise asynchronous circuit. As yet another example, in some embodiments, some or all of the digital circuits 206 in the circuit stack 210 may each comprise other types of circuits in the circuit stack 210.

According to various embodiments, at least a portion of the one or more low speed digital circuits 206 is stacked to reduce power consumption. As shown in FIG. 2, at least two low speed digital circuits 206 may be stacked vertically, in series to form a circuit stack 210. In various embodiments, a pair of vertically adjacent digital circuits 206 in the circuit stack 210 are connected at a node 211 (e.g., central node) between the digital circuits 206 in the pair of vertically adjacent digital circuits. For example, in the illustrated example of FIG. 2, depicting a high speed digital circuit connected to a circuit stack 210 comprising two low speed digital circuits 206, the low speed digital circuits in the circuit stack 210 may be connected at a central node 211. In various embodiments, the central node 211 has a node voltage that is less than the supply voltage 202 applied to the digital circuit system 200 and correspond to a reduced voltage that is applied to each of the low speed digital circuits 206 in the circuit stack 210. Additionally, or alternatively, in various embodiments, the node voltage is substantially same as the supply voltage at which the low speed digital circuits 206 are configured to operate, run, or otherwise driven. In various embodiments, the node voltage is a fraction of the supply voltage 202 applied to the digital circuit system 200 (e.g., V_{DD} /n) based on a number of low speed digital circuits in the circuit stack. For example, V_{DD} represents the supply voltage (V_{DD}) 202 applied to the digital circuit system 200 and n represents the number of digital circuits in the circuit stack 210.

The low speed digital circuits 206 in the circuit stack 210 may be similar or different low speed digital circuits. By way of example, in one example implementation, a first low speed digital circuit 206 in the circuit stack 210 may comprise a I channel filter and the second low speed digital circuit 206 in the circuit stack 210 may comprise a Q channel filter.

By stacking the low speed digital circuits 206 vertically, in series on top of each other, example embodiments of the present disclosure maintain the supply voltage (V_{DD}) 202 while also driving each of the low speed digital circuits 206 in the circuit stack 210 at the node voltage, which is a reduced supply voltage (e.g., V_{DD} /n) relative to the supply voltage (V_{DD}) 202 for the one or more high speed digital circuits 204 and/or supply voltage (V_{DD}) applied to the digital circuit system 200. By way of example, in an example implementation, the supply voltage (V_{DD}) 202 being applied to the circuit stack 210 may be 1.2V which is the same as the supply voltage (V_{DD}) 202 for the one or more high speed digital circuits 204 (corresponding to the supply voltage applied to the digital circuit system 200), but the individual low speed digital circuits 206 in the circuit stack 210 may each be applied a reduced supply voltage (e.g., V_{DD} /n) of 0.6V corresponding to the node voltage.

As described above, power consumption associated with a digital circuit may be proportional to the supply voltage (or multiples thereof) at which the digital circuit is being driven/run. In this regard, by reducing the supply voltage of the low speed digital circuits 206 via vertical, series stacking, the power consumption associated with the low speed digital circuits 206 is reduced. Moreover, by stacking the low speed digital circuits 206, example embodiments of the present disclosure obviate the need for voltage regulators (which, as discussed above, dissipate power). In this regard, example embodiments of the present disclosure further reduce power consumption associated with the digital circuit system 200 by utilizing the power that would otherwise have been wasted if the top low speed digital circuit 206 in the circuit stack 210 had been a voltage regulator (e.g., implemented to reduce the voltage supply for the bottom low speed digital circuit 206). In this regard, by stacking multiple digital circuits, embodiments of the present disclosure use power that would otherwise have been wasted (e.g., if voltage regulator is utilized) to do useful work (e.g., drive/run another low speed digital circuit such as the top low speed digital circuit 206 in the illustrated example of FIG. 2).

In various embodiments, the low power digital circuit system 200 comprises one or more level shifter components 212 (e.g., level shifters). The level shifter component 212 may comprise a device configured to facilitate transitioning from one voltage level to another voltage level such as, for example, a high voltage domain to a low voltage domain (and/or vice versa). As shown in FIG. 2, in various embodiments, a level shifter component 212 may be leveraged to transition from lower supply voltage used to run the low speed digital circuits 206 in the circuit stack 210 to the supply voltage 202 for the one or more high speed digital circuits 204 (e.g., from low supply voltage domain to high supply voltage domain 220). In some embodiments, the level shifter component 212 may comprise a transistor or other device designed to facilitate or perform voltage level shifting.

In various embodiments, the loads of the low speed digital circuits 206 in the circuit stack 210 is balanced using an architecture design, such that the current consumed by the low speed digital circuits 206 in the circuit stack 210 are substantially identical. Particularly, the loads of each of the low speed digital circuits 206 in the circuit stack may be balanced to maintain the node voltage at the central node 211 between each pair of vertically adjacent digital circuits in the circuit stack 210 at V_{DD} /n. For example, the low speed digital circuits 206 may correspond to, or otherwise function, as multiple loads arranged in series with a reduced supply voltage (e.g., node voltage of V_{DD} /n, where V_{DD} is the supply voltage for the one or more high speed digital circuits 204 and n is the number of digital circuits in the circuit stack 210.

In some embodiments, the load balancing architecture design comprises a load balancing circuit configured to sense instantaneous unequal current demand with respect to the digital circuits 206 in the circuit stack 210, and enforce toggling in response to detecting unequal current demand. For example, in some embodiments, the circuit stack 210 may comprise a load balancing circuit configured to sense instantaneous unequal current demand with respect to the digital circuits 206 in the circuit stack 210. The load balancing circuit may comprise a portion of the circuit stack 210. For example, the load balancing circuit may represent a portion of the circuit stack 210. In some embodiments, each digital circuit in the circuit stack 210 may be associated with a load balancing circuit such as, for example, a canary circuit. In some embodiments, the load balancing architecture design for balancing the loads of the low speed digital circuits in the circuit stack 210 may comprise a canary circuit, an analog circuit, and/or other load balancing circuits. The analog circuit, for example, may be configured to constantly maintain V_{DD}/n between a pair of vertically adjacent low speed digital circuits in the circuit stack 210.

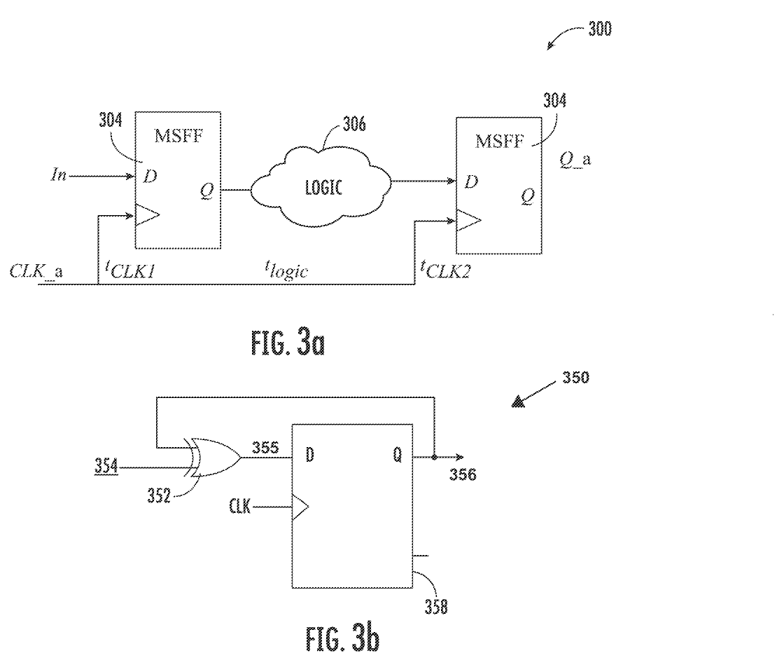

FIG. 3a illustrates an example canary circuit 300 in accordance with at least some embodiments of the present disclosure. FIG. 3b illustrates an example dummy circuit 350 in accordance with at least some embodiments of the present disclosure. In some embodiments, the canary circuit 300 is configured to sense instantaneous unequal current demand with respect to the digital circuits 206 in the circuit stack 210 and enforce toggling in response to detecting unequal current demand. For example, in some embodiments, the circuit stack 210 may comprise a load balancing circuit such as, for example, canary circuit 300 configured to regulate the node voltage (VDD/n) at the node 211 by selectively enabling dummy circuits (described further below) associated with the digital circuits 206 in the circuit stack 210. For example, in some embodiments, instantaneous unequal current demand may be sensed in critical path replica and toggling of dummy circuit(s) enforced. In this regard, in some embodiments, a circuit stack may include at least one critical path replica and at least one power controlling toggle flip-flop. The critical path replica, for example, may comprise canary circuit(s) such as canary circuit(s) 300. The power controlling toggle flip-flop, for example, may comprise dummy circuit(s) such as dummy circuit(s) 350. As shown in FIG. 3b, in some embodiments, a dummy circuit 350 may comprise a logical gate 352 coupled to a flip-flop 358 (e.g., flip-flop circuit, flip-flop device, or similar terms). In some embodiments, the flip-flop 358 is a D-type flip-flop (e.g., delay flip-flop, or the like). In some embodiments, the logical gate 352 is an XOR gate. It will be appreciated that in some embodiments, the flip-flop 358 may be other flip-flop types/configuration and/or the logical gate 352 may be other types of logical gate without departing from the scope of the present disclosure. The logical gate 352 may be configured to receive an input 354 that enables toggling in the dummy circuit 350 so as to enable the power dissipation (e.g., the necessary power dissipation). As shown in FIG. 3b, in some embodiments, the flip-flop 358 may be configured to receive the output 355 of the logical gate 352 as input (e.g., input D) and generate an output 356 (e.g., output Q). In this regard, in some embodiments, a circuit stack may comprise a plurality of dummy circuits configured to be turned on and/or turned off based on current demand and/or otherwise as necessary for load balancing in the circuit stack.

As described herein, in some embodiments, each digital circuit 206 in the circuit stack 210 may comprise a dummy circuit. In some examples, the canary circuit 300 may comprise one or more flip-flops 304 (e.g., one or more master-slave flip-flops 304) and logic 306. As described above, the canary circuit 300 may be configured to sense unequal current demand among the digital circuits in a circuit stack 210 and enforce toggling. For example, the canary circuit 300 may be configured to detect when a digital circuit 206 in the circuit stack 210 is consuming more current than other digital circuits in the circuit stack 210 or consuming less current than other digital circuits in the circuit stack 210 and enforce toggling designed to balance the current demand between stacked digital circuits.

The canary circuit 300 may be configured to enforce toggling by causing the current demand of a digital circuit drawing less current relative to other digital circuits in the circuit stack 210 to increase its current demand, thus balancing the load across the digital circuits in the circuit stack 210. In some embodiments, the circuit stack 210 may comprise one or more dummy circuits (such as one or more dummy circuits 350) that are leveraged to enforce toggling. For example, the one or more dummy circuits may comprise a portion of the low speed digital circuits 206 in the circuit stack 210 (e.g., the one or more dummy circuits may be part of the digital circuits 206 in the circuit stack 210. For example, in the illustrated example of FIG. 2, a first dummy circuit may comprise or otherwise is part of the top low speed digital circuit 206 in the pair of low speed digital circuits in the circuit stack 210, and a second dummy circuit may comprise or is otherwise part of the bottom low speed digital circuit 206 in the pair of low speed digital circuits 206 in the circuit stack 210. In the regard, a dummy circuit may be a circuit configured to selectively load the digital circuits 206 in the circuit stack 210 to ensure load balancing between the digital circuits. For example, in some embodiments, each low speed digital circuit 206 in the circuit stack 210 may be associated with at least one dummy circuit that is configured for increasing the current demand of the respective low speed digital circuit 206 when the low speed digital circuit 206 is detected as drawing less current relative to other low speed digital circuits in the circuit stack 210.

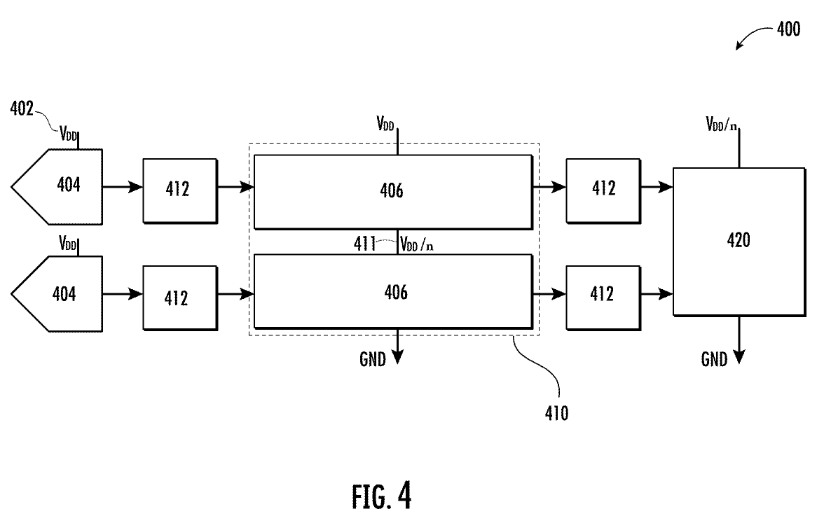

FIG. 4 provides a block diagram of an example low power mixed signal digital circuit system 400 in accordance with at least some embodiments of the present disclosure. Specifically, FIG. 4 illustrates a portion of an example integrated circuit (e.g., for an electronic device or system) implementing circuit stacking techniques according to at least some embodiments of the present disclosure. The depiction of the example low power mixed signal digital circuit system 400 is not intended to limit or otherwise confine the embodiments described and contemplated herein to any particular configuration of elements or systems, nor is it intended to exclude any alternative configurations or systems for the set of configurations and systems that can be used in connection with embodiments of the present disclosure. Rather, FIG. 4 and the low power mixed signal digital circuit system 400 disclosed therein is merely presented to provide an example basis and context for the facilitation of some of the features, aspects, and uses of the methods, apparatuses, and systems disclosed and contemplated herein. It will be understood that while many of the aspects and components presented in FIG. 4 are shown as discrete, separate elements, other configurations may be used, including configurations that combine, omit, separate, and/or add aspects and/or components.

In various embodiments, the low power mixed signal digital circuit system 400 may comprise one or more mixed signal circuits 404 and/or one or more full speed digital circuits 406. For example, the illustrated example of FIG. 4 may comprise a system of mixed signal circuits and digital circuits representative of the low power mixed signal digital circuit system 400 configured to perform one or more functionalities. In some embodiments, the one or more mixed signal circuits 404 may be connected to the one or more full speed digital circuits 406. For example, the mixed signal circuits 404 may be connected to a stack of full speed digital circuits 406, as further described below. In some embodiments, the one or more mixed signal circuits 404 may be connected in parallel to the one or more full speed digital circuits 406 (e.g., stack of full speed digital circuits 406).

In some embodiments, a full speed digital circuit 406 may be similar to a high speed digital circuit in non-mixed signal digital circuit system, such as the low power digital circuit system 200 in that the supply voltage required to drive/run the high speed digital circuits 204 and the full speed digital circuits 406 may the same. A non-limiting of a mixed signal circuit is an analog to digital converter (ADC). In the illustrated example of FIG. 4, the one or more mixed signal circuits 404, for example may comprise two ADCs (e.g., used in communication applications or other applications). It would be appreciated that the mixed signal circuits may comprise other mixed signal circuits.

The one or more mixed signal circuits 404 may require a higher supply voltage relative to the full speed digital circuits 406. In some embodiments, the one or more mixed signal circuits 404 are configured to operate, run, or otherwise driven at a supply voltage (V_{DD}) 402 that is greater than the supply voltage at which the one or more full speed digital circuits 406 are configured to operate, run, or otherwise driven. In such some embodiments, a full speed digital circuit 406 may be configured to operate, run, or otherwise driven at a supply voltage that is less than the one or more mixed signal circuits 404.

By way of example, in some implementations, the one or more mixed signal circuits 404 may be configured to operate, run, or otherwise driven at a supply voltage (V_{DD}) 402 of 2.4V. In some embodiments, the supply voltage (V_{DD}) 402 of the one or more mixed signal circuits 404 corresponds to the supply voltage (V_{DD}) applied to the mixed signal digital circuit system 400 and/or the IC in which the one or more mixed signal circuits 404 are embodied and/or may be a constant supply voltage from the voltage source. The supply voltage 402 (V_{DD}) may be generated or supplied from a variety of voltage source types such as, but not limited to, batteries, DC-DC converter, and/or the like.

The digital circuit system 400 and/or the circuit stack 410 thereof may comprise any of a plurality of circuit types such as, but not limited to synchronous circuits, asynchronous circuits, and/or the like. In some embodiments, at least a portion of the mixed signal digital circuit system 400 may comprise a synchronous circuit. For example, a mixed signal circuit and/or a full speed digital circuit thereof may comprise a synchronous circuit. In some embodiments, at least one of the full speed digital circuits in the circuit stack 410 comprises a synchronous circuit. Additionally, or alternatively, in some embodiments, at least a portion of the mixed signal digital circuit system 400 may comprise an asynchronous circuit. For example, a mixed signal circuit and/or a full speed digital circuit thereof may comprise an asynchronous circuit. In some embodiments, at least one of the full speed digital circuits in the circuit stack 410 comprises an asynchronous circuit. In this regard, the circuit stack 410 may comprise any of a plurality of circuit types. For example, in some embodiments, some or all of the digital circuits 406 in the circuit stack 410 may each comprise a synchronous circuit. As another example, in some embodiments, some or all of the digital circuits 406 in the circuit stack 410 may each comprise asynchronous circuit. As yet another example, in some embodiments, some or all of the digital circuits 406 in the circuit stack 410 may each comprise other types of circuits in the circuit stack 410.

According to various embodiments, at least a portion of the one or more full speed digital circuits 406 is stacked to reduce power consumption. As shown in FIG. 4, at least two full speed digital circuits 406 may be stacked vertically, in series to form a circuit stack 410. In various embodiments, a pair of vertically adjacent digital circuits 206 in the circuit stack 210 are connected at a node 411 (e.g., central node) between the digital circuits 206 in the pair of vertically adjacent digital circuits. For example, in the illustrated example of FIG. 4, depicting two mixed signal circuits 404 (e.g., such as two ADC circuits) connected to a circuit stack 410 comprising two full speed digital circuits 406, the full speed digital circuits 406 in the circuit stack 410 may be connected at a central node 411. In various embodiments, the central node 411 has a node voltage that is less than the supply voltage 402 applied to the mixed signal digital circuit system 400 and corresponds to a reduced voltage that is applied to each of the full speed digital circuits 406 in the circuit stack 410. Additionally, or alternatively, in various embodiments, the node voltage is substantially the same as the supply voltage at which the full speed digital circuits 406 are configured to operate, run, or otherwise driven. In various embodiments, the node voltage is a fraction of the supply voltage 202 applied to the mixed signal digital circuit system 400 (e.g., V_{DD} /n) based on a number of low speed digital circuits in the circuit stack. For example, V_{DD} may represent the supply voltage 402 applied to the mixed signal digital circuit system 400 and n may represent the number of full speed digital circuits in the circuit stack 410.

The full speed digital circuits 406 in the circuit stack 410 may be similar or different full speed digital circuits. By stacking the full speed digital circuits 406 vertically, in series on top of each other, example embodiments of the present disclosure maintain the supply voltage (V_{DD}) 402 while also driving each of the full speed digital circuits 406 in the circuit stack 410 at the node voltage (e.g., V_{DD} /n), which is a reduced supply voltage relative to the supply voltage (V_{DD}) 402 for the one or more mixed signal circuits 404 and/or supply voltage (V_{DD}) applied to the mixed signal digital circuit system 400. For example, in an example implementation, the supply voltage (V_{DD}) 402 being applied to the circuit stack 410 may be 2.4V which may be the same as the supply voltage 402 for the one or more mixed signal circuits 404 (corresponding to the supply voltage applied to the mixed signal digital circuit system 400 ), but the individual full speed digital circuits 406 in the circuit stack 410 may each be applied a reduced supply voltage (e.g., V_{DD} /n) of 1.2V corresponding to the node voltage.

As described above, power consumption associated with a digital circuit may be proportional to the supply voltage (or multiples thereof) at which the digital circuit is being driven/run. In this regard, by reducing the supply voltage of the full speed digital circuits 406 via vertical, series stacking, the power consumption associated with the full speed digital circuits 406 is reduced. Moreover, by stacking the full speed digital circuits 406, example embodiments of the present disclosure obviate the need for voltage regulators (which, as discussed above, dissipate power). In this regard, example embodiments of the present disclosure further reduce power consumption associated with the mixed signal digital circuit system 400 by utilizing the power that would otherwise have been wasted if a voltage regulator had been used to reduce the voltage for the full speed digital circuits 406 in the circuit stack 410.

In various embodiments, the low power mixed signal digital circuit system 400 comprise one or more level shifter components 412. A level shifter component 412 may comprise a device configured to facilitate transitioning from one voltage level to another voltage level such as, for example, a high voltage domain to a low voltage domain (and/or vice versa). In some embodiments, a level shifter component 412 may be leveraged to transition from a higher supply voltage used to run some of the circuits in the mixed signal digital circuit system 400 to low supply voltage used to run some other circuits in the system, or vice versa. For example, as shown in FIG. 4, one or more level shifter components 412 may be used to transition from the circuit stack 410 voltage to a supply voltage domain 420. In some embodiments, as described above, the level shifter component 412 may comprise a transistor or other device designed to facilitate or perform voltage level shifting.

In various embodiments, the loads of the full speed digital circuits 406 in the circuit stack 410 are balanced using an architecture design, such that the current consumed by the full speed digital circuits 406 in the circuit stack 410 are substantially identical. Particularly, the loads of the full speed digital circuits 406 in the circuit stack 410 may be balanced to maintain the node voltage at the central node 411 between each pair of vertically adjacent full speed digital circuits 406 in the circuit stack 410 at V_{DD} /n. For example, the full speed digital circuits 406 may correspond to, or otherwise function, as multiple loads arranged in series with a reduced supply voltage (e.g., node voltage) of V_{DD} /n, where V_{DD} is the supply voltage for the one or more mixed signal circuits 404 and n is the number of full speed digital circuits in the stack.

In some embodiments, the load balancing architecture design comprises a load balancing circuit configured to sense instantaneous unequal current demand with respect to the full speed digital circuits 406 in the circuit stack 410 and enforce toggling in response to detecting unequal current demand. For example, in some embodiments, the circuit stack 410 may comprise a load balancing circuit configured to sense instantaneous unequal current demand with respect to the digital circuits 406 in the circuit stack 410. The load balancing circuit may comprise a portion of the circuit stack 410. For example, the load balancing circuit may represent a portion of the circuit stack 410. In some embodiments, each digital circuit 406 in the circuit stack 410 may be associated with a load balancing circuit such as, for example, a canary circuit. In some embodiments, the load balancing architecture design may comprise a canary circuit, an analog circuit, or other load balancing circuits. The analog circuit, for example, may be configured to constantly maintain a V_{DD}/n between a pair of vertically adjacent full speed digital circuits in the circuit stack 410. In some embodiments, a canary circuit such as the canary circuit 300 described with reference to FIG. 3a may be used for load balancing. For example, in some embodiments, the circuit stack 410 may comprise a load balancing circuit such as, for example, canary circuit 300 configured to regulate the node voltage (VDD/n) at the node 411 by selectively enabling dummy circuits associated with the digital circuits in the circuit stack 410. As described herein, in some embodiments, each digital circuit 406 in the circuit stack 410 may comprise a dummy circuit such as dummy circuit 350 described above.

For example, the canary circuit 300 may configured to sense instantaneous unequal current demand with respect to the full speed digital circuits 406 in the circuit stack 410, and enforce toggling in response to detecting unequal current demand. For example, the canary circuit 300 may be configured to detect when a full speed digital circuit 406 in the circuit stack 410 is consuming more current than other full speed digital circuits 406 in the circuit stack 410 or consuming less current than other digital circuits in the circuit stack 410 and enforce toggling designed to balance the current demand between the full speed digital circuits 406.

For example, the canary circuit 300 when implemented in a low power mixed signal digital circuit system 400 may enforce toggling by causing the current demand of a full speed digital circuit 406 drawing less current relative to other full speed digital circuits 406 in the circuit stack 410 to increase its current demand, thus balancing the load across the full speed digital circuits 406 in the circuit stack 410. In some embodiments, the circuit stack 410 may comprise one or more dummy circuits that are leveraged to enforce toggling. For example, as described above, the one or more dummy circuits may comprise a portion of the full speed digital circuits in the circuit stack 410. For example, in the illustrated example of FIG. 4, a first dummy circuit may comprise or otherwise is part of the top full speed digital circuit 406 in the pair of full speed digital circuits in the circuit stack 410, and a second dummy circuit may comprise or is otherwise part of the bottom full speed digital circuit 406 in the pair of full speed digital circuits. For example, each full speed digital circuit 406 in the circuit stack 410 may be associated with at least one dummy circuit that is configured for increasing the current demand of the respective full speed digital circuit when detected (e.g., via a canary circuit or other sensing circuits) as drawing less current relative to other full speed digital circuits in the circuit stack 410.

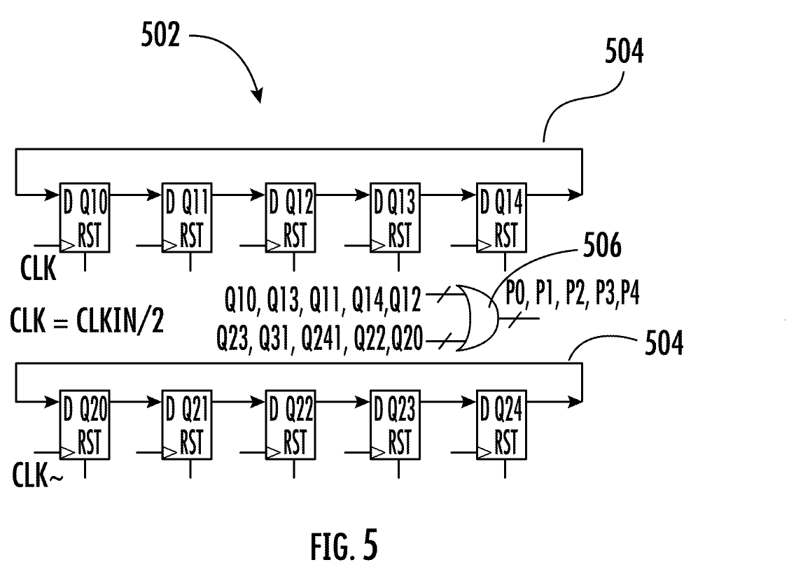

FIG. 5 illustrates an example multi-phase clock generator 502 in accordance with at least some embodiments of the present disclosure. By way of example, the multi-phase clock generator may comprise a pair of counters 504 (e.g., running at, for example, a low frequency) and stacked on top of each other. Shown in FIG. 5 is also a combinational logic 506 to combine the two clock phases. A simulation (Monte Carlo simulation) with respect to the multi-phase clock generator 502 showed three times power saving when the pair of counters 504 are stacked in accordance with at least some example embodiments of the present disclosure compared to when they are not stacked.

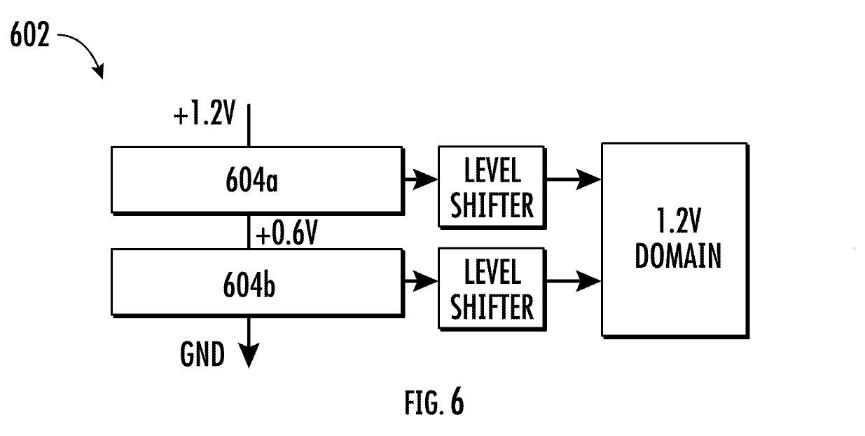

FIG. 6 illustrates an example moving average filter 602 in accordance with at least some embodiments of the present disclosure. The illustrated moving average filter 602, for example, may be an 8-Tap moving average filter comprising a pair of filters stacked on top of each other with a voltage supply (V_{DD}) of 1.2V applied to the circuit stack and a node voltage of 0.6V applied to each filter in the circuit stack. The moving average filter 602, for example, may comprise a I channel filter 604a stacked on top of a Q channel filter 604b. An example timing diagram showed ten times power saving when the I channel filter 604a and Q channel filter 604b are stacked on top of each other in accordance with at least some example embodiments of the present disclosure compared to when they are not stacked.

### CONCLUSION

Many modifications and other embodiments of the disclosure set forth herein will come to mind to one skilled in the art to which this disclosure pertains having the benefit of the teachings presented in the foregoing description and the associated drawings. Therefore, it is to be understood that the embodiments are not to be limited to the specific embodiments disclosed and that modifications and other embodiments are intended to be included within the scope of the appended claims. Moreover, although the foregoing descriptions and the associated drawings describe example embodiments in the context of certain example combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

While this specification contains many specific implementation details, these should not be construed as limitations on the scope of any disclosures or of what may be claimed, but rather as descriptions of features specific to particular embodiments of particular disclosures. Certain features that are described herein in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single product or packaged into multiple products.

Thus, particular embodiments of the subject matter have been described. Other embodiments are within the scope of the following claims. In some cases, the actions recited in the claims can be performed in a different order and still achieve desirable results. In addition, the processes depicted in the accompanying figures do not necessarily require the particular order shown, or sequential order, to achieve desirable results. In certain implementations, multitasking and parallel processing may be advantageous.

Further, while this detailed description has set forth some embodiments of the present disclosure, the appended claims may cover other embodiments of the present disclosure which differ from the described embodiments according to various modifications and improvements. Further, within the appended claims, unless the specific terms “means for” or “step for” is used within a given claim, it is not intended that the claim be interpreted under 35 U.S.C. § 112, paragraph (f).

1. A digital circuit system comprising:
a high speed digital circuit, wherein a first supply voltage is being applied to the high speed digital circuit;
a circuit stack comprising a first low speed digital circuit and a second low speed digital circuit stacked vertically on top relative to the first low speed digital circuit, wherein each of the first low speed digital circuit and the second low speed digital circuit are (i) configured for being driven at a second supply voltage that is less than the first supply voltage, and (ii) are connected at a central node with a node voltage that is substantially same as the second supply voltage; and
one or more level shifter components configured for transitioning between the first supply voltage and the second supply voltage.

2. The digital circuit system of claim 1, wherein the first low speed digital circuit and the second low speed digital circuit are connected in series.

3. The digital circuit system of claim 1, wherein the node voltage is a fraction of the first supply voltage based on a number of low speed digital circuits in the circuit stack.

4. The digital circuit system of claim 1, wherein the high speed digital circuit is configured for being driven at the first supply voltage.

5. The digital circuit system of claim 1, wherein at least one of the first low speed digital circuit or the second low speed digital circuit comprise a synchronous circuit.

6. The digital circuit system of claim 1, wherein at least one of the first low speed digital circuit or the second low speed digital circuit comprise an asynchronous circuit.

7. The digital circuit system of claim 1, wherein the circuit stack further comprises a load balancing circuit configured to maintain the node voltage.

8. The digital circuit system of claim 7, wherein the circuit stack further comprises one or more dummy circuits, wherein the load balancing circuit is configured to detect instantaneous unequal current demand with respect to the circuit stack, and enforce toggling in response to detecting the unequal current demand using at least a portion of the one or more dummy circuits.

9. The digital circuit system of claim 8, wherein a first dummy circuit of the one or more dummy circuits comprises a portion of the second low speed digital circuit.

10. The digital circuit system of claim 8, wherein a second dummy circuit of the one or more dummy circuits comprises a portion of the first low speed digital circuit.

11. A digital circuit system comprising:
one or more mixed signal circuits, wherein a first supply voltage is being applied to the one or more mixed signal circuits;
a circuit stack comprising a first full speed digital circuit and a second full speed digital circuit stacked vertically on top relative to the first full speed digital circuit, wherein each of the first full speed digital circuit and the second full speed digital circuit are (i) configured for being driven at a second supply voltage that is less than the first supply voltage, and (ii) are connected at a central node with a node voltage that is substantially same as the second supply voltage; and
one or more level shifter components configured for transitioning between the first supply voltage and the second supply voltage.

12. The digital circuit system of claim 11, wherein the first full speed digital circuit and the second full speed digital circuit are connected in series.

13. The digital circuit system of claim 11, wherein the node voltage is a fraction of the first supply voltage based on a number of full speed digital circuits in the circuit stack.

14. The digital circuit system of claim 11, wherein the one or more mixed signal circuits is configured for being driven at the first supply voltage.

15. The digital circuit system of claim 11, wherein at least one of the first full speed digital circuit or the second full speed digital circuit comprise a synchronous circuit.

16. The digital circuit system of claim 11, wherein at least one of the first full speed digital circuit or the second full speed digital circuit comprise an asynchronous circuit.

17. The digital circuit system of claim 11, wherein the one or more mixed signal circuits comprise one or more ADCs.

18. The digital circuit system of claim 11, wherein the circuit stack further comprises a load balancing circuit configured to maintain the node voltage and one or more dummy circuits, wherein the load balancing circuit is configured to detect instantaneous unequal current demand with respect to the circuit stack, and enforce toggling in response to detecting the unequal current demand using at least a portion of the one or more dummy circuits.

19. The digital circuit system of claim 18, wherein a first dummy circuit of the one or more dummy circuits comprises a portion of the second full speed digital circuit.

20. The digital circuit system of claim 18, wherein a second dummy circuit of the one or more dummy circuits comprises a portion of the first full speed digital circuit.
